(19) United States
(12) Patent Application Publication
(10) Pub. No.: US 2018/0136275 A1
(43) Pub. Date: May 17, 2018

(54) TEMPERATURE-MEASURING APPARATUS, INSPECTION APPARATUS, AND CONTROL METHOD

(71) Applicant: SEIKO EPSON CORPORATION, Tokyo (JP)

(72) Inventors: Sakiko SHIMIZU, Matsumoto-shi (JP); Akira IKEDA, Chino-shi (JP)

(73) Assignee: SEIKO EPSON CORPORATION, Tokyo (JP)

(21) Appl. No.: 15/799,431

(22) Filed: Oct. 31, 2017

(30) Foreign Application Priority Data
Nov. 14, 2016 (JP) 2016-221167

(51) Int. Cl. G01R 31/28

(52) U.S. Cl. CPC G01R 31/2875

(57) ABSTRACT

A temperature-measuring apparatus includes a heat source capable of changing a heat generation temperature, a temperature sensor that detects a temperature of a predetermined position other than a measurement target accommodated in a measurement subject, and a temperature computation portion that computes a temperature of the measurement target on the basis of heat balance characteristics of the temperature of the measurement target, a temperature of the heat source, and the temperature of the predetermined position, the temperature of the heat source, and the detected temperature of the predetermined position.

### BACKGROUND

### 1. Technical Field

The present invention relates to a temperature-measuring apparatus and the like which measure the internal temperatures of measurement subjects.

### 2. Related Art

In processes for manufacturing electronic components such as integrated circuits (IC), in order to decrease initial failure in advance and exhibit the reliability of the electronic components, inspection is carried out regarding the performance or functions of the manufactured electronic components (burn-in tests). As the burn-in tests, there are inspections that are carried out at high temperatures. For example, JP-A-2014-76519 discloses an electronic component inspection apparatus in which electronic components are transported to a socket that inputs/outputs electrical signals for inspection and are pressed onto the socket while being heated so as to connect terminals of the electronic components to the socket, thereby inspecting the electrical characteristics of the electronic components.

However, the above-described inspections that are carried out at high temperatures are carried out in a state in which electronic components are heated to temperatures necessary for inspection (for example, 150° C. or the like). Since it is not possible to install or insert temperature-measuring devices into electronic components, methods in which the internal temperatures of electronic components are presumptively measured from the operation status of elements having temperature characteristics such as diodes or transistors mounted in the electronic components and heat sources are controlled to heat the electronic components so that the internal temperatures of the electronic components reach the above-described necessary temperatures (hereinafter, referred to as “target temperatures”) are known. However, the above-described methods of the related art are not applicable in a case in which the electronic components are considered as black boxes as a whole and, furthermore, there have been problems in that the presumption of the internal temperatures of the entire electronic components from the operation status of elements has a margin of error, individual differences among electronic components, the fluctuation of ambient heat environments, and the like cause unevenness in terms of the actual internal temperature, and there are cases in which electronic components cannot be heated to the target temperatures. In addition, although it is necessary to cause the internal temperatures of electronic components to reach the target temperature during inspection, it cannot be said that the methods of the related art are highly accurate at all times as methods for measuring the internal temperatures of electronic components.

Hitherto, description has been made about electronic components, but the same problems can be caused for any components other than electronic components as long as it is necessary to heat the internal temperatures to the target temperatures for inspection and the like.

### SUMMARY

An advantage of some aspects of the invention is to provide a technique with which the internal temperatures of measurement subjects can be accurately measured and the transition of the internal temperatures can be monitored.

A first aspect of the invention is directed to a temperature-measuring apparatus including a heat source capable of changing a heat generation temperature, a temperature sensor that detects a temperature of a predetermined position other than a measurement target accommodated in a measurement subject, and a temperature computation portion that computes a temperature of the measurement target on the basis of heat balance characteristics of the temperature of the measurement target, a temperature of the heat source, and the temperature of the predetermined position, the temperature of the heat source, and the detected temperature of the predetermined position.

As another aspect of the invention, the invention may be configured as a control method of a temperature-measuring apparatus including a heat source capable of changing a heat generation temperature and a measurement target accommodated in a measurement subject, the control method including: computing a temperature of the measurement target on the basis of heat balance characteristics of the temperature of the measurement target, a temperature of the heat source, and the temperature of the predetermined position, the temperature of the heat source, and the detected temperature of the predetermined position.

According to the first aspect of the invention or the like, it is possible to compute the temperature of the measurement target accommodated in the measurement subject from the temperature of the heat source and the detected temperature of the predetermined position using the heat balance characteristics of the temperature of the measurement target, the temperature of the heat source, and the temperature of the predetermined position. According to the aspect, it becomes possible to accurately measure the internal temperatures of measurement subjects and monitor the transition of the internal temperatures.

As a second aspect of the invention, the temperature-measuring apparatus of the first aspect of the invention may be configured to further include: a control portion that controls the temperature of the heat source on the basis of the computed temperature of the measurement target.

According to the second aspect of the invention, it is possible to realize the temperature control of the heat source with which the temperature of the measurement target is set to a predetermined temperature.

As a third aspect of the invention, the temperature-measuring apparatus of the first or second aspect of the invention may be configured to further include: a mounting portion on which the measurement subject is mounted. As a fourth aspect of the invention, the temperature-measuring apparatus of the third aspect of the invention may be configured such that the temperature sensor detects a temperature of the mounting portion as the temperature of the predetermined position.

According to the third aspect of the invention or the like, it is possible to compute the temperature of the measurement target by detecting and using the temperature of the mounting portion on which the measurement subject is mounted.

As a fifth aspect of the invention, the temperature-measuring apparatus of the third or fourth aspect of the invention may be configured such that the temperature-measuring apparatus further includes: a conveyance portion that holds and conveys the measurement subject to the mounting portion and halts at a predetermined halt position during measurement, and the heat source is provided in the conveyance portion.

According to the fifth aspect of the invention, it is possible to heat the measurement subject (measurement target) using the conveyance portion that holds and conveys the measurement subject to the mounting portion and halts at the predetermined position between measurements. In addition, between measurements, it is possible to compute the temperature of the measurement target accommodated in the heated measurement subject.

As a sixth aspect of the invention, the temperature-measuring apparatus of any one of the first to fifth aspects of the invention may be configured such that the temperature computation portion variably sets the heat balance characteristics depending on heat environments.

According to the sixth aspect of the invention, it is possible to compute the temperature of the measurement target using the heat balance characteristics varied depending on heat environments.

As a seventh aspect of the invention, the temperature-measuring apparatus of the sixth aspect of the invention may be configured such that the temperature computation portion variably sets the heat balance characteristics depending on the heat environments on the basis of any one of a temperature in an apparatus chassis and a convection degree.

According to the seventh aspect of the invention, it is possible to compute the temperature of the measurement target using the heat balance characteristics varied depending on the temperature in the apparatus chassis and the convection degree in the apparatus chassis.

As an eighth aspect of the invention, an inspection apparatus including the temperature-measuring apparatus of any one of the first to seventh aspects of the invention, in which the measurement target is an electronic circuit, may be configured.

According to the eighth aspect of the invention, in the inspection apparatus of electronic circuits, it is possible to accurately measure the temperature of electronic circuits which are inspection targets and monitor the transition of the temperature.

As a ninth aspect of the invention, an inspection apparatus including the temperature-measuring apparatus of anyone of the third to fifth aspects of the invention, in which the measurement target is an electronic circuit and the mounting portion has a socket for the electronic circuit, a circuit inspection treatment device which is installed in a predetermined space in the apparatus chassis, has an operation compensation temperature that is lower than the temperature of the heat source, and is connected to the socket with an electrical wire, and a cooling device for cooling the circuit inspection treatment device, in which the temperature computation portion variably sets the heat balance characteristics depending on a heat environment in the predetermined space, may be configured.

According to the ninth aspect of the invention, the circuit inspection treatment device having an operation compensation temperature that is lower than the temperatures of the heat sources is installed in the predetermined space of the chassis, and this circuit inspection treatment device is cooled using the cooling device. Therefore, although the heat environment in the predetermined space in which the circuit inspection treatment device is installed may have an influence on a temperature of the electronic circuit, the heat balance characteristics varied depending on the heat environment in the predetermined space are used, and thus it is possible to realize computation in consideration of the influence in the computation of the temperature of the electronic circuit.

As a tenth aspect of the invention, the inspection apparatus of the ninth aspect of the invention may be configured such that the temperature sensor detects a temperature of a position close to the electrical wire in the socket as the temperature of the predetermined position.

According to the tenth aspect of the invention, it is possible to compute the temperature of the electronic circuit by detecting and using temperatures at positions in which heat flows from the heat sources easily flow.

### BRIEF DESCRIPTION OF THE DRAWINGS

The invention will be described with reference to the accompanying drawings, wherein like numbers reference like elements.

FIG. 1 is a schematic perspective view showing an overall constitution example of an IC test handler.

FIG. 2 is a pattern diagram showing a schematic constitution example of an inspection unit.

FIG. 3 is a view showing a heat flow path model.

FIG. 4 is a view showing a data constitution example of a heat balance characteristic table.

FIG. 5 is a view describing a computation accuracy of an IC temperature T_{IC}.

FIG. 6 is a block diagram showing a principal function constitution example of a control device.

FIG. 7 is a flowchart showing a flow of treatments carried out by the control device.

FIG. 8 is a view showing a data constitution example of a heat balance characteristic table in the modification example.

FIG. 9 is a pattern diagram showing a schematic constitution example of an inspection unit in the modification example.

### DESCRIPTION OF EXEMPLARY EMBODIMENTS

Hereinafter, a preferred embodiment of the invention will be described with reference to the accompanying drawings. In the following description, an integrated circuit (IC) which is an electronic circuit will be used as a measurement subject, and an IC test handler used to inspect the electrical characteristics of IC at high temperatures will be exemplified. IC test handlers are installed and used in outsourced semiconductor assembly and tests (OSAT) or the like which undertake post-processes (assembly or inspection/tests) of semiconductor-manufacturing processes. The invention is not limited by the embodiment described below, and applicable formats of the invention are also not limited to the following embodiment. In addition, in the drawing, the same portion will be given the same reference symbol.

### Overall Constitution

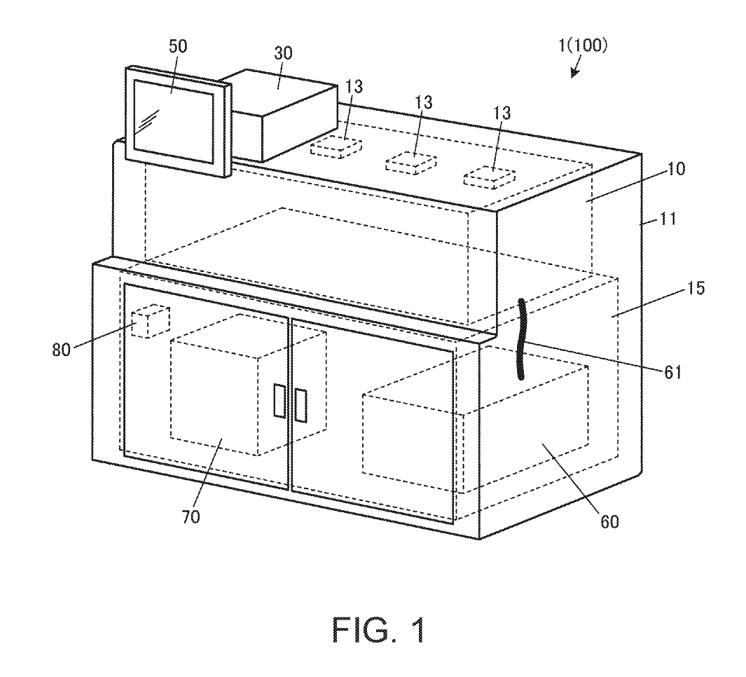

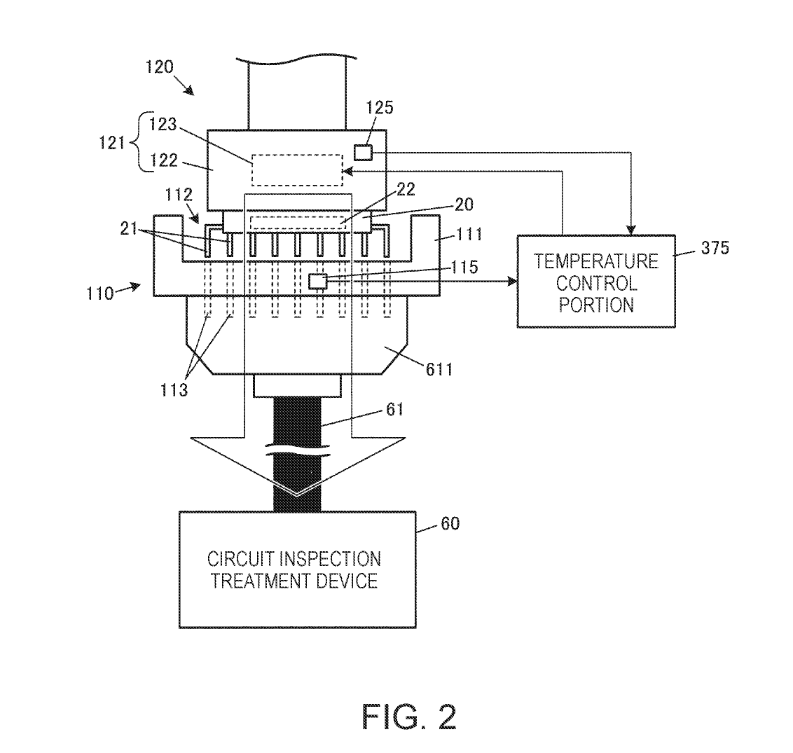

FIG. 1 is a schematic perspective view showing an overall constitution example of an IC test handler 1 which is an inspection apparatus 100, and FIG. 2 is a pattern diagram showing a schematic constitution example of an inspection unit 10 embedded into the IC test handler 1. The IC test handler 1 includes an inspection unit 10 constituting the upper portion of a substantially cuboid-shape chassis 11, a control device 30 controlling the operation of the inspection unit 10, a display device 50 for displaying the state of the inspection unit 10 and the like, and a plurality of neutralization devices (ionizer) 13 for removing static electricity in the inspection unit 10. In addition, the IC test handler 1 has an accommodation space 15 provided in the lower portion of the chassis 11 as a predetermined space in the apparatus chassis and includes a circuit inspection treatment device 60, a cooling device 70, and a thermometer 80 which are provided in the accommodation space 15.

The inspection unit 10 includes, as principal constitutions, a mounting portion 110 which is installed at an appropriate place in the inspection unit 10 and mounts an IC package 20 accommodating an IC 22 which is an inspection target (also a measurement target of internal temperatures described below) and an adsorption hand 120 as a conveyance portion which moves in the inspection unit 10 and sequentially conveys IC packages 20 toward the mounting portion 110. FIG. 2 shows a state in which the adsorption hand 120 conveys the IC package 20 up to the mounting portion 110.

The adsorption hand 120 adsorbs and holds the IC package 20 on a front end surface side using a suction mechanism, not shown, and conveys the IC package 20. This adsorption hand 120 has a heating portion 121 in a front end portion and is capable of heating and holding the IC package 20 (IC 22) at the same time. The heating portion 121 is constituted by burying a heat generator (hereinafter, referred to as “hand heater”) 123 which is a heat source in a heat conductor 122.

The hand heater 123 is constituted so as to be capable of changing a heat generation temperature in a predetermined temperature range, and the heat generation temperature is controlled using a temperature control portion 375 constituting the control device 30. This hand heater 123 is intended to heat the IC 22 to a predetermined target temperature (for example, 150° C. or the like), and the temperature range in which the heat generation temperature can be changed is set to be, for example, room temperature to approximately 180° C.

The mounting portion 110 detachably holds the IC package 20 and has a socket 111 that conducts electrical signals between the circuit inspection treatment device 60 and the IC 22. The socket 111 has a recess portion 112 formed on an upper surface, and the IC package 20 is mounted in the socket 111 using the adsorption hand 120 at the time of inspection. In addition, the socket 111 includes a plurality of socket pins (electrical wires) 113 in an array which have one end portion exposed in the recess portion 112 and are electrically connected to individual terminals 21 of the IC 22 mounted in the recess portion 112. The other end portion of each of the socket pins 113 is connected to the end of an electrical wire of a corresponding cable 61 through a cable connector 611 and is connected to the circuit inspection treatment device 60.

The operation of the inspection unit 10 regarding the inspection of one IC 22 will be briefly described. First, the adsorption hand 120 adsorbs and holds the IC package 20 accommodating the IC 22 which is an inspection target, conveys the IC package up to the mounting portion 110, and mounts the IC package in the recess portion 112 of the socket 111. At this time, the adsorption hand 120 moves downward from the position in FIG. 2 and presses the IC package 20 into the recess portion 112, whereby the respective terminals 21 of the IC 22 are brought into contact with the corresponding socket pins 113 so as to mount the IC package 20 in the socket 111, and the adsorption hand remains halted for a predetermined time at the moved-down position as a halt position. During this halt, inspection is carried out, and, at the time of inspection, in the heating portion 121, the hand heater 123 generates heat at a predetermined heat generation temperature and heats the IC package 20 through the heat conductor 122 in contact with the IC package 20. The heating may be initiated even before the mounting of the IC package 20 into the socket 111. Therefore, a state in which the inside of the IC 22 is heated to the target temperature is formed. In addition, the circuit inspection treatment device 60 carries out an inspection treatment while the adsorption hand 120 remains halted and inspects the electrical characteristics of the IC 22 which is the inspection target. When the inspection ends, the adsorption hand 120 conveys the IC package 20 from the mounting portion 110, and the process proceeds for inspection regarding the subsequent IC 22.

In the inspection unit 10 operating as described above, the adsorption hand 120 includes a first temperature detector 125 for detecting the temperature of the heating portion 121. The first temperature detector 125 may be installed at an arbitrary position in the heating portion 121 such as the inside, surface, or the like of the heating portion 121.

The mounting portion 110 includes a second temperature detector 115 which is a temperature sensor that detects the temperature of a predetermined position other than the IC 22. The second temperature detector 115 may be installed at an arbitrary position in the socket 111, but is preferably installed at a position which is lower than the IC package 20 (on the downstream side of a heat flow direction) and is close to any one of the socket pins 113. As described below, a heat flow from the hand heater 123 moves in a heat flow direction shown by an arrow in FIG. 2, and heat is discharged toward the accommodation space 15 (external air) on the lower side through the socket 111. In addition, the temperature control portion 375 computes (assumes) a temperature (hereinafter, referred to as “IC temperature”) T_{IC} of the IC 22 accommodated in the IC package 20 using a heat flow path model in which heat flows from the hand heater 123 toward the accommodation space 15. Since the main body of the socket 111 is formed of a material having a low heat conductivity such as a polyetheretherketone (PEEK) resin, heat flows transmitting through the socket 111 mainly gather in the socket pins 113 which are conductors having a high heat conductivity. Therefore, the use of the temperature of the socket pins 113 rather than the temperature of the main body portion as a socket temperature T_{SKT} described below enables the accurate computation of the IC temperature T_{IC}.

The control device 30 controls the operation of the inspection unit 10 regarding the inspection of the IC 22. In this control device 30, the temperature control portion 375 computes and uses the IC temperature T_{IC} of the inspection target and controls the heat generation temperature of the hand heater 123 as needed so that the IC temperature T_{IC} reaches the target temperature.

The circuit inspection treatment device 60 is constituted of a computer or the like, input and output electrical signals to and from the IC 22 which is the inspection target, and carries out a treatment for inspecting the electrical characteristics of the IC 22 (inspection treatment). Specifically, the circuit inspection treatment device 60 outputs inspection electrical signals to the IC 22 through the socket. In addition, the circuit inspection treatment device analyzes electrical signals that are input from the IC 22 in response to the outputted electrical signals, thereby determining whether the electrical characteristics are favorable or poor and selecting favorable products/poor products.

The cooling device 70 is intended to cool the circuit inspection treatment device 60 and air-cools the accommodation space 15 by feeding indoor air into the accommodation space 15 using, for example, a fan and discharging the air in the accommodation space 15. Since the operation guaranteed temperature of the circuit inspection treatment device 60 is approximately room temperature, heat flowing from the hand heater 123 is discharged into the accommodation space 15 as described above. The cooling device 70 dissipates heat discharged into the accommodation space 15 as described above and prevents the temperature of the circuit inspection treatment device 60 from increasing. Due to this cooling device 70, the temperature of the accommodation space 15 is maintained at approximately room temperature (approximately 24° C. to 25° C.). The cooling device is not limited to air cooling-type cooling devices, and fanless-type cooling devices or water cooling-type cooling devices may also be used. In addition, air conditioners cooling the circuit inspection treatment device using heat media may also be used as the cooling device 70.

The thermometer 80 detects the temperature of the accommodation space 15 and outputs the temperature to the control device 30.

### Principle

In the present embodiment, the temperature of the hand heater 123 is set to a high temperature such as 150° C. or the like, the circuit inspection treatment device 60 and the like are installed on the lower side of the inspection unit 10 in the accommodation space 15, and the temperature of the accommodation space 15 is lower than the heat generation temperature of the hand heater 123. As long as the cooling device 70 is being driven, the temperature of the accommodation space 15 is approximately room temperature. Therefore, heat flowing from the hand heater 123 moves downwards as shown by the arrow in FIG. 2 and is discharged into the accommodation space 15 through the socket 111 and the cable 61. Therefore, herein, as a heat flow path along which heat flows from a predetermined heat source position P_{H} to an arbitrary position (hereinafter, referred to as “internal space position”) P_{OUT} in the accommodation space 15, two heat flow paths that is a heat flow path which starts from the heat source position P_{H}, passes through an internal position (hereinafter, referred to as “position in the IC”) P_{IC} in the IC 22 which is the measurement target (also the inspection target), and reaches the internal space position P_{OUT} (a first heat flow path) and a heat flow path which starts from the heat source position P_{H}, passes through a predetermined position (hereinafter, referred to as “socket position”) P_{SKT} in the socket 111, and reaches the internal space position P_{OUT} (a second heat flow path) will be considered. The heat source position P_{H} is, for example, the installation position of the first temperature detector 125, and the socket position P_{SKT} is the installation position of the second temperature detector 115.

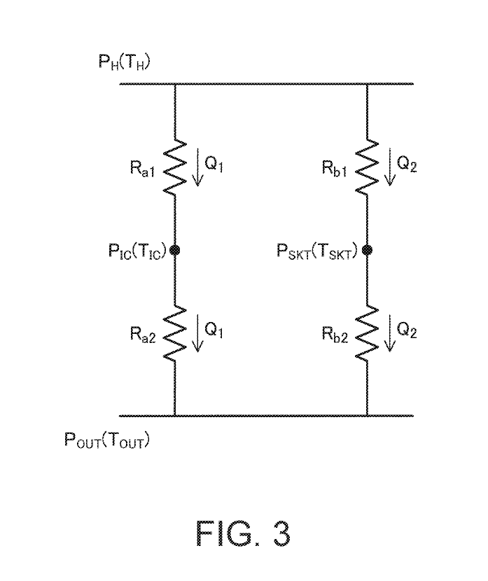

When a heat flow moves along the first heat flow path or the second heat flow path, the heat flow is affected by the inflow of heat from the outside and the outflow of heat to the outside during the movement process. In the present embodiment, this heat exchange will be referred to as “heat balance”. When an electrical circuit-like model of the first heat flow path and the second heat flow path is produced in consideration of this heat balance, it is possible to build a heat flow path model as in FIG. 3. As a path from the heat source position P_{H} to the position in the IC P_{IC} or a path from the position in the IC P_{IC} to the internal space position P_{OUT}, a path from the heat source position P_{H} to the socket position P_{SKT}, and a path from the socket position P_{SKT} to the internal space position P_{OUT}, a variety of paths can be considered. In the heat flow path model of FIG. 3, each of the paths is expressed as one heat resistance. The values of the respective heat resistances are unknown.

In the heat flow path model of FIG. 3, a heat flow Q₁ moving along the first heat flow path can be expressed by Expression (1) using a temperature (hereinafter, referred to as “heat source temperature”) T_{H} of the heat source position P_{H}, an IC temperature T_{IC} which is the temperature of the position in the IC P_{IC}, a temperature (hereinafter, referred to as “internal space temperature”) T_{OUT} of the internal space position P_{OUT}, a heat resistance Rₐ₁ between the heat source position P_{H} and the position in the IC P_{IC}, and a heat resistance Rₐ₂ between the position in the IC P_{IC} and the internal space position P_{OUT}. In addition, a heat flow Q₂ moving along the second heat flow path can be expressed by Expression (2) using the heat source temperature T_{H}, a temperature (hereinafter, referred to as “socket temperature”) T_{SKT} of the socket position P_{SKT}, the internal space temperature T_{OUT}, a heat resistance R_{b1} between the heat source position P_{H} and the socket position P_{SKT}, and a heat resistance R_{b2} between the socket position P_{SKT} and the internal space position P_{OUT}.

$$\begin{matrix}{Q}_{1} = \frac{{T}_{H} - {T}_{IC}}{{R}_{a 1}} = \frac{{T}_{IC} - {T}_{OUT}}{{R}_{a 2}} & ( 1 ) \\ {Q}_{2} = \frac{{T}_{H} - {T}_{SKT}}{{R}_{b 1}} = \frac{{T}_{SKT} - {T}_{OUT}}{{R}_{b 2}} & ( 2 )\end{matrix}$$

When Expression (1) is rearranged for the IC temperature T_{IC}, Expression (3) is obtained, and, when Expression (2) is rearranged for the socket temperature T_{SKT}, Expression (4) is obtained.

$$\begin{matrix}{T}_{IC} = \frac{{R}_{a 2}}{{R}_{a 1} + {R}_{a 2}} {T}_{H} + \frac{{R}_{a 1}}{{R}_{a 1} + {R}_{a 2}} {T}_{OUT} & ( 3 ) \\ {T}_{SKT} = \frac{{R}_{b 2}}{{R}_{b 1} + {R}_{b 2}} {T}_{H} + \frac{{R}_{b 1}}{{R}_{b 1} + {R}_{b 2}} {T}_{OUT} & ( 4 )\end{matrix}$$

Next, in order to compute the IC temperature T_{IC}, the element of the internal space temperature T_{OUT} is removed from Expression (3) and Expression (4). In order for that, the coefficient of the internal space temperature T_{OUT} in Expression (3) is rearranged as Expression (5), and the coefficient of the internal space temperature T_{OUT} in Expression (4) is rearranged as Expression (6).

$$\begin{matrix}\frac{{R}_{a 1}}{{R}_{a 1} + {R}_{a 2}} = a & ( 5 ) \\ \frac{{R}_{b 1}}{{R}_{b 1} + {R}_{b 2}} = b & ( 6 )\end{matrix}$$

The coefficient a represents the proportion of the heat resistance Rₐ₁ in the total heat resistances of the first heat flow path. This represents the influence on heat flows moving through the first heat flow path of heat balance generated by the heat resistance Rₐ₁ and can be considered as a coefficient representing the heat balance characteristics at the position in the IC P_{IC}. What has described above also applies to the coefficient b, and the coefficient b is considered as a coefficient representing the heat balance characteristics at the socket position P_{SKT}.

At this time, Expression (3) and Expression (4) can be rearranged as Expression (7) and Expression (8) respectively.

T_{SC}=(1−a)T_{H}+aT_{OUT} (7)

T_{SKT}=(1−b)T_{H}+bT_{OUT} (8)

Therefore, from Expression (7) and Expression (8), the heat source temperature T_{H} can be represented by, for example, Expression (9).

$${T}_{H} = \frac{b}{b - a} {T}_{IC} - \frac{a}{b - a} {T}_{SKT} = \frac{1}{1 - \frac{a}{b}} {T}_{IC} - \frac{\frac{a}{b}}{1 - \frac{a}{b}} {T}_{SKT} \qquad ( 9 )$$

Here, as the ratio of the coefficient a defined by Expression (5) to the coefficient b defined by Expression (6), a heat balance relative coefficient D represented by Expression (10) is introduced.

$$D = \frac{a}{b} \qquad ( 10 )$$

Using the heat balance relative coefficient D, Expression (9) can be rearranged as Expression (11).

$${T}_{H} = \frac{1}{1 - D} {T}_{IC} - \frac{D}{1 - D} {T}_{SKT} \qquad ( 11 )$$

In addition, when Expression (11) is rearranged for the IC temperature T_{IC}, Expression (12) is obtained.

T_{IC}=DT_{SKT}−(D−1)T_{H} (12)

In Expression (12), the heat source temperature T_{H} can be detected using the first temperature detector 125, and the socket temperature T_{SKT} can be detected using the second temperature detector 115, and thus the elements are all known. However, the thermal resistances Rₐ₁, Rₐ₂, R_{b1}, and R_{b2} are unknown, and thus the value of the heat balance relative coefficient D is also unknown. Therefore, in the present embodiment, the heat balance relative coefficient D is corrected.

When Expression (12) is rearranged for the heat balance relative coefficient D, Expression (13) is obtained.

$$D = \frac{{T}_{IC} - {T}_{H}}{{T}_{SKT} - {T}_{H}} \qquad ( 13 )$$

Here, the IC temperature T_{IC} is a temperature to be obtained, and the value thereof is not evident. However, since the heat balance relative coefficient D can be obtained from Expression (13) as long as a reference value (hereinafter, referred to as “reference IC temperature”) T_{IC0} of the IC temperature T_{IC} can be separately measured, it is possible to correct the heat balance relative coefficient D.

The reference IC temperature T_{IC0} is specified by measuring the actual value of the temperature of the IC 22 using a separate measurement method in advance. In addition, when the detected temperature of the first temperature detector 125 at the time of measuring the actual value is considered as a reference heat source temperature T_{H0}, and the detected temperature of the second temperature detector 115 is considered as a reference socket temperature T_{SKT0}, the heat balance relative coefficient D can be computed as in Expression (14) using Expression (13).

$$D = \frac{{T}_{IC 0} - {T}_{H 0}}{{T}_{SKT 0} - {T}_{H 0}} \qquad ( 14 )$$

However, the heat resistance Rₐ₂ in the heat flow path from the position in the IC P_{IC} to the internal space position P_{OUT} or the heat resistance R_{b2} in the heat flow path from the socket position P_{SKT} to the internal space position P_{OUT} is affected by the heat environment in the accommodation space 15. In addition, this heat environment varies depending on a convection degree in the accommodation space 15. Therefore, in the present embodiment, the convection degree in the accommodation space 15 is defined by the combination of the driving state of the cooling device 70 and the driving state of the neutralization devices 13, and the heat balance relative coefficient D is computed and corrected in advance by acquiring the reference IC temperature T_{IC0} or the reference heat source temperature T_{H0} and the reference socket temperature T_{SKT0} in a heat environment (that is, in the corresponding driving states of the cooling device 70 and the neutralization devices 13) corresponding to each of the convection degrees.

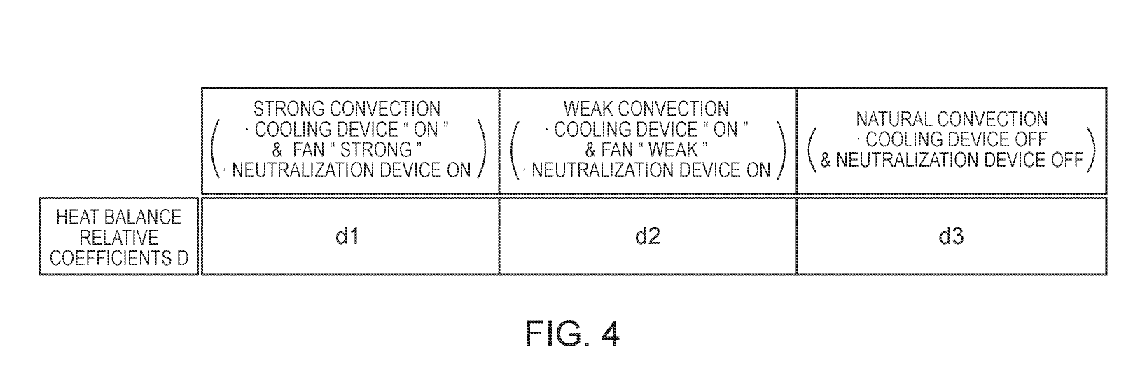

FIG. 4 is a view showing a data constitution example of a heat balance characteristic table in which the corrected heat balance relative coefficient D is set. As shown in FIG. 4, in the heat balance characteristic table, values of the heat balance relative coefficient D are separately stored depending on three steps of the convection degree of “strong convection”, “weak convection”, and “natural convection”. In the example of FIG. 4, it is assumed that the air volume of the fan constituting the cooling device 70 can be selected to be “strong” or “weak”, and “strong convection” refers to a case in which the cooling device 70 is being driven, the air volume of the fan is set to be “strong”, and the neutralization devices 13 are being driven. “Weak convection” refers to a case in which the cooling device 70 is being driven, the air volume of the fan is set to be “weak”, and the neutralization devices 13 are being driven. “Natural convection” refers to a case in which both the cooling device 70 and the neutralization devices 13 remain halted.

After the heat balance relative coefficient D is corrected as described above, the heat source temperature T_{H} and the socket temperature T_{SKT} are detected as needed, and the IC temperature T_{IC} is computed according to Expression (12) using the above-described temperatures and the heat balance relative coefficient D. The computed IC temperature T_{IC} may be appropriately displayed on the display device 50 and presented to users.

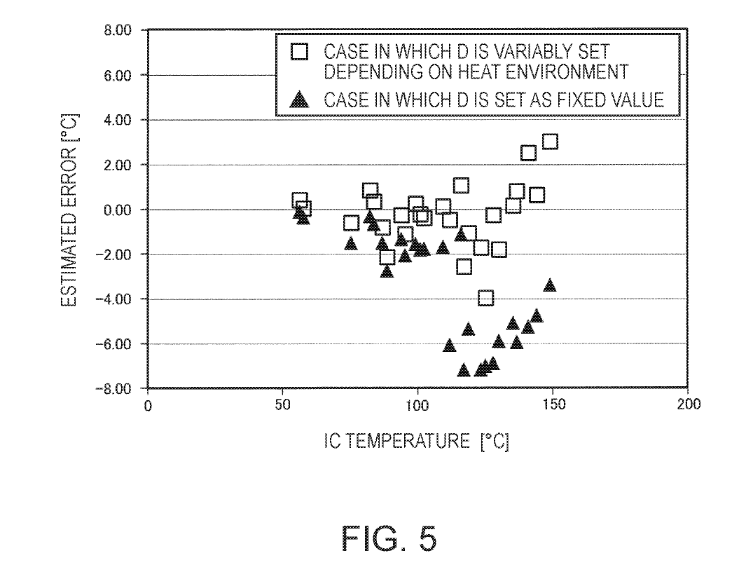

FIG. 5 is a view describing the computation accuracy of the IC temperature T_{IC} and shows estimated errors plotted for a case in which the IC temperature T_{IC} is computed using the heat balance relative coefficient D as a fixed value and a case in which the IC temperature T_{IC} is computed by reading and using the heat balance relative coefficient D corresponding to the convection degree from the heat balance characteristic table while changing the driving states of the cooling device 70 and the neutralization devices 13. The estimated errors were obtained by measuring the actual value of the IC temperature T_{IC} in conjunction. As shown in FIG. 5, the IC temperature T_{IC} can be more highly accurately measured by, for example, considering the convection degree in the accommodation space 15 as the heat environment and variably setting (amending) the heat balance relative coefficient D.

### Function Constitution

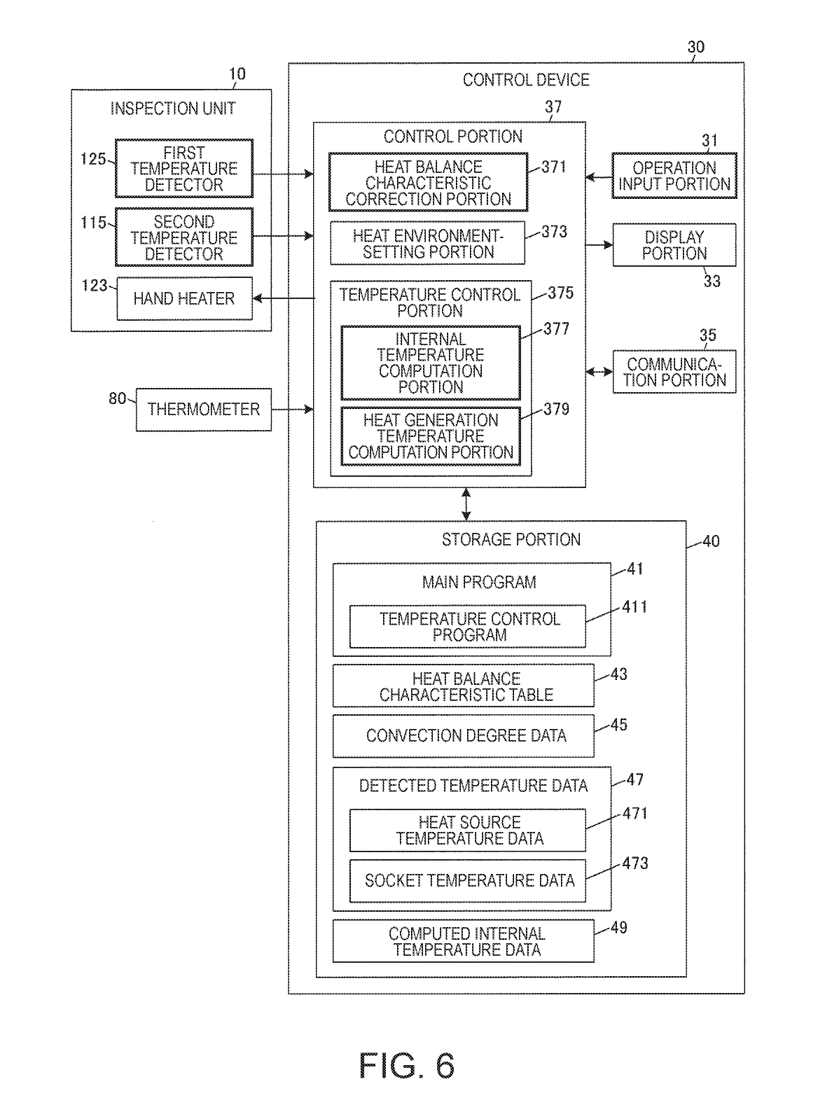

FIG. 6 is a block diagram showing a principal function constitution example of the control device 30. As shown in FIG. 6, the control device 30 includes an operation input portion 31, a display portion 33, a communication portion 35, a control portion 37, and a storage portion 40 and constitutes the temperature-measuring apparatus together with the inspection unit 10 or the thermometer 80.

The operation input portion 31 receives a variety of operation inputs from users and outputs operation input signals corresponding to the operation inputs to the control portion 37. The operation input portion can be realized using a button switch, a lever switch, a dial switch, a touch panel, or the like.

The display portion 33 is realized using a display device such as a liquid crystal display (LCD), an organic electroluminescence display (OELD), an electronic paper display, or the like and displays a variety of information on the basis of display signals from the control portion 37. In FIG. 1, the display device 50 corresponds to this display portion.

The communication portion 35 is a communication device for sending and receiving data to and from the outside on the basis of the control by the control portion 37. For example, the control device 30 is capable of sending or receiving necessary data to and from the circuit inspection treatment device 60 through the communication portion 35. As the communication method of the communication portion 35, a variety of methods such as a method of wireless connection using wireless communication, a method of wire connection using cables based on predetermined communication standards, and a method of connection through an intermediate device, which is called a cradle or the like and also functions as a charger, are applicable.

The control portion 37 controls the input and output of data to and from a variety of functional portions, executes a variety of arithmetic processing on the basis of predetermined programs or data, operation input signals from the operation input portion 31, detected temperatures input from the first temperature detector 125 as needed, detected temperatures input from the second temperature detector 115 as needed, the temperature of the accommodation space 15 input from the thermometer 80 as needed, and the like, and controls the operation of the inspection unit 10 regarding the inspection of the IC 22. The control portion can be realized using, for example, a microprocessor such as a central processing unit (CPU) or a graphics processing unit (GPU) or an electronic component such as an application specific integrated circuit (ASIC), a field programmable gate array (FPGA), or an IC memory.

The control portion 37 includes a heat balance characteristic correction portion 371, a heat environment-setting portion 373 and a temperature control portion 375.

The heat balance characteristic correction portion 371 acquires the reference IC temperature T_{IC0} before inspection and, simultaneously, acquires the detected temperature detected using the first temperature detector 125 as the reference heat source temperature T_{H0} and the detected temperature detected using the second temperature detector 115 as the reference socket temperature T_{SKT0}. In addition, the heat balance relative coefficient D is corrected by computing the heat balance relative coefficient D according to Expression (14). In more detail, the heat balance characteristic correction portion 371 computes the heat balance relative coefficient D by acquiring the reference IC temperature T_{IC0}, the reference socket temperature T_{SKT0}, and the reference heat source temperature T_{H0} while changing the convection degree in the accommodation space 15 and corrects the heat balance relative coefficient D for each of a plurality of convection degrees, thereby generating the heat balance characteristic table 43.

The heat environment-setting portion 373 sets the convection degree in the actual accommodation space 15. For example, the heat environment-setting portion generates convection degree data which set the driving state of the cooling device 70 and the driving state of the neutralization devices 13. The driving state of the cooling device 70 includes the setting of whether or not the cooling device being driven (driven/halted) and the air volume setting of the fan (“strong” or “weak”). For the neutralization devices 13, the heat environment-setting portion sets whether or not the neutralization devices are driven (driven/halted). In addition, the heat environment-setting portion 373 renews convection degree data 45 each time the driving states of the cooling device 70 and the neutralization devices 13 are changed.

The temperature control portion 375 controls the heat generation temperature of the hand heater 123 so that the IC temperature T_{IC} reaches the target temperature. The temperature control portion 375 includes an internal temperature computation portion 377 and a heat generation temperature computation portion 379.

The internal temperature computation portion 377 computes the IC temperature T_{IC} according to Expression (12) using the heat balance relative coefficient D, the heat source temperature T_{H}, and the socket temperature T_{SKT}. At this time, regarding the heat balance relative coefficients D, the value of the corresponding heat balance relative coefficient D is read from the heat balance characteristic table 43 and used according to the convection degree data 45.

The heat generation temperature computation portion 379 computes the heat generation temperature of the hand heater 123 on the basis of the difference between the IC temperature T_{IC} computed by the internal temperature computation portion 377 and the target temperature.

The storage portion 40 is realized using a storage medium such as an IC memory, a hard disc, or an optical disc. In the storage portion 40, programs for operating the control device 30 so as to realize a variety of functions of the control device 30 or data that are used during the execution of the programs are stored in advance or temporarily stored each time a treatment is carried out. The control portion 37 and the storage portion 40 maybe connected to each other not only using internal bus circuits in the device but also using communication lines such as local area network (LAN) or internet. In this case, the storage portion 40 may also be realized using a storage device that is different from the control device 30.

The storage portion 40 stores a main program 41, a heat balance characteristic table 43, the convection degree data 45, detected temperature data 47, and computed internal temperature data 49.

The control portion 37 reads and executes the main program 41, thereby controlling the operation of the inspection unit 10 regarding the inspection of the IC 22. The main program 41 includes a temperature control program 411 for causing the control portion 37 to function as the heat balance characteristic correction portion 371, the heat environment-setting portion 373 and the temperature control portion 375. The respective portions have been described to be realized in a software manner by causing the control portion 37 to read and execute the temperature control program 411, but can also be realized in a hardware manner by constituting electronic circuits that are exclusive for the respective portions.

The heat balance characteristic table 43 stores the values of the heat balance relative coefficient D for each of the convection degree which are corrected by the heat balance characteristic correction portion 371 (refer to FIG. 4).

The convection degree data 45 stores the convection degrees in the accommodation space 15 which are set by the heat environment-setting portion 373.

The detected temperature data 47 includes heat source temperature data 471 and socket temperature data 473. The heat source temperature data 471 stores the heat source temperatures T_{H} that are detected as needed using the first temperature detector 125 in chronological order. The socket temperature data 473 stores the socket temperatures T_{SKT} that are detected as needed using the second temperature detector 115 in chronological order.

The computed internal temperature data 49 stores the IC temperatures T_{IC} that are computed as needed using the internal temperature computation portion 377 in chronological order.

### Flow of Treatments

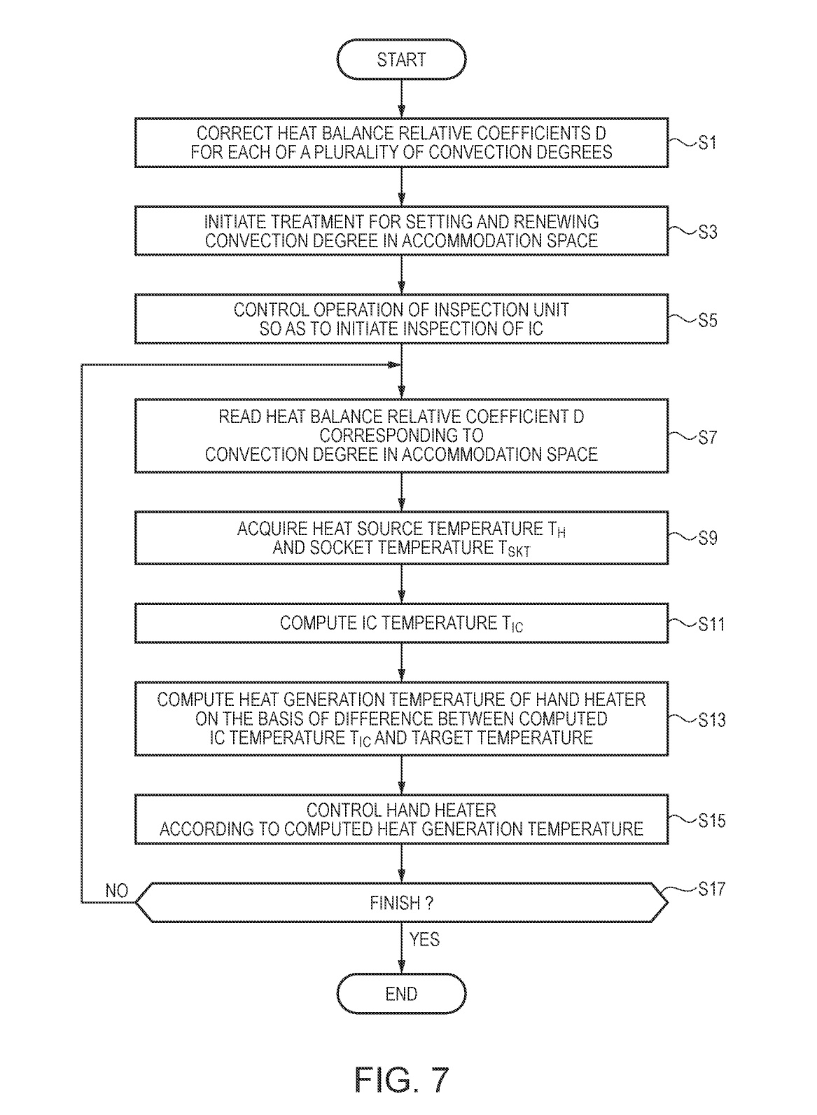

FIG. 7 is a flowchart showing a flow of treatments carried out by the control device 30. The treatments to be described herein can be realized by causing the control portion 37 to read and execute the main program 41 including the temperature control program 411 from the storage portion 40 and causing the respective portions in the IC test handler 1 to operate.

First, the heat balance characteristic correction portion 371 acquires the reference IC temperature T_{IC0} for each of the plurality of convection degrees that are defined in advance, detects the reference heat source temperature T_{H0} and the reference socket temperature T_{SKT0}, and computes and corrects the heat balance relative coefficient D using Expression (14) (Step S1). The computed heat balance relative coefficient D for each of the convection degrees is stored in the storage portion 40 as the heat balance characteristic table 43. In addition, a treatment in which the heat environment-setting portion 373 acquires the actual driving state of the cooling device 70 and the actual driving state of the neutralization devices 13 as needed and sets the driving states as the convection degree in the accommodation space 15 is initiated (Step S3). Due to the above-described treatment, the convection degree data 45 are generated and renewed.

After that, the control portion 37 controls the operation of the inspection unit 10 and initiates the inspection of the IC 22 (Step S5). In addition, treatments of Step S7 to Step S15 are repeated each time the adsorption hand 120 adsorbs the IC package 20 accommodating a new IC 22 which is an inspection target and mounts the IC package on the mounting portion 110, whereby the hand heater 123 is caused to generate heat so that the IC temperatures T_{IC} which sequentially become inspection targets in inspection that is initiated in Step S5 reach the target temperature.

That is, first, in Step S7, the internal temperature computation portion 377 reads the corresponding heat balance relative coefficient D according to the convection degree data from the heat balance characteristic table 43. Subsequently, the internal temperature computation portion 377 acquires the detected temperature detected using the first temperature detector 125 as the heat source temperatures T_{H} and the detected temperature detected using the second temperature detector 115 as the socket temperatures T_{SKT} (Step S9). In addition, the internal temperature computation portion 377 computes the IC temperature T_{IC} according to Expression (12) using the heat balance relative coefficient D read in Step S7, the heat source temperature T_{H} and the socket temperature T_{SKT} which have been acquired in Step S9 (Step S11).

Once the IC temperature T_{IC} is computed, the heat generation temperature computation portion 379 computes the heat generation temperature of the hand heater 123 on the basis of the difference between the IC temperature T_{IC} and the target temperature (Step S13). In addition, the temperature control portion 375 controls the hand heater 123 according to the computed heat generation temperature (Step S15).

After that, there is no more IC 22 which is an inspection target, the process returns to Step S7, and the above-described treatments are repeated until the present treatment finishes (Step S17: NO).

As described above, according to the present embodiment, it is possible to compute the IC temperatures T_{IC} from the heat source temperatures T_{H} detected using the first temperature detector 125 as needed and the socket temperatures T_{SKT} detected using the second temperature detector 115 as needed using the heat balance relative coefficients D computed and corrected by acquiring the reference IC temperature T_{IC0}, the reference heat source temperature T_{H0}, and the reference socket temperature T_{SKT0} as the heat balance characteristics of the respective temperatures. At this time, it is possible to variably set the heat balance relative coefficient D in consideration of the convection degree in the accommodation space 15. According to this, it is possible to accurately measure the temperature of the IC 22 and monitor the transition of the temperature.

In addition, it is possible to compute the heat generation temperature of the hand heater 123 on the basis of the difference between the computed IC temperature T_{IC} and the target temperature and control the heat generation temperature of the hand heater 123 so that the computed IC temperature T_{IC} reaches the target temperature. Here, even when the hand heater 123 generates heat at the same heat generation temperature, the actual temperatures of the IC 22 may not be even due to, for example, individual differences among the IC packages 20 such as surface roughness, the fluctuation of the heat environment in the chassis 11 such as the accommodation space 15, and the like. Additionally, there are cases in which the temperatures of the IC 22 are not even due to the deviation of the adsorption positions of the IC package 20 by the adsorption hand 120. However, according to the present embodiment, it is possible to control the hand heater 123 as needed while computing the IC temperatures T_{IC}. Therefore, it is possible to carry out inspection in a state in which the IC 22 is appropriately heated to the target temperature, and thus the reliability improves.

### Modification Example

The method for heating the IC package 20 is not limited to the method in which the IC package 20 is heated by being brought into contact with the heating portion including the hand heater 123 and may be a method in which the IC package 20 is put into a chamber (constant-temperature tank) having an inside controlled to a predetermined temperature and is heated to the target temperature.

In the above-described embodiment, the convection degree in the accommodation space 15 is defined by the combination of the driving state of the cooling device 70 and the driving state of the neutralization devices 13, and the heat balance characteristic table 43 is set in advance by computing the heat balance relative coefficient D for each of the convection degrees. In addition, the IC temperatures T_{IC} is computed using the heat balance relative coefficient D of the convection degree matching the actual driving state of the cooling device 70 and the actual driving state of the neutralization devices 13. However, the convection degree may be specified by installing a wind speed meter in the accommodation space 15 and detecting the wind speed in the accommodation space 15. In addition, the heat balance relative coefficient D corresponding to the specified convection degree maybe used. In this case, the heat balance characteristic table may be generated by correcting the heat balance relative coefficient D while changing the wind speed in the accommodation space 15.

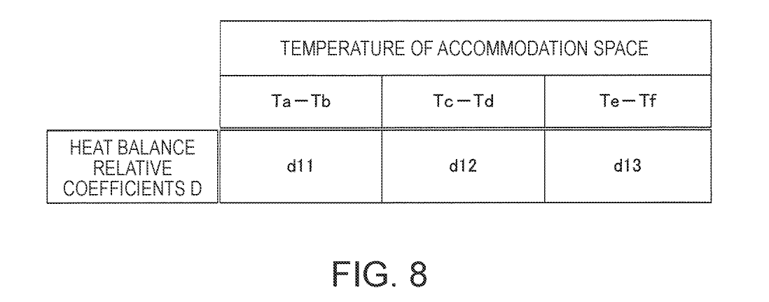

In addition, a constitution in which the heat balance relative coefficient D is variably set using the temperature in the chassis 11 in addition to the convection degree may also be employed. In this case, the heat balance characteristic table is generated in advance by correcting the heat balance relative coefficient D while changing the temperature in the accommodation space 15. In addition, the temperature of the accommodation space 15 detected using the thermometer 80 is acquired as needed, and the corresponding heat balance relative coefficient D is used to compute the IC temperature T_{IC}. According to this, it is possible to consider the temperature of the accommodation space 15 as the heat environment and variably set the heat balance relative coefficient D, and thus the IC temperature T_{IC} can be accurately measured. FIG. 8 is a view showing a data constitution example of the heat balance characteristic table in the present modification example. As shown in FIG. 8, in the heat balance characteristic table of the present modification example, the values of the heat balance relative coefficient D are stored depending on the stepwise temperature ranges.

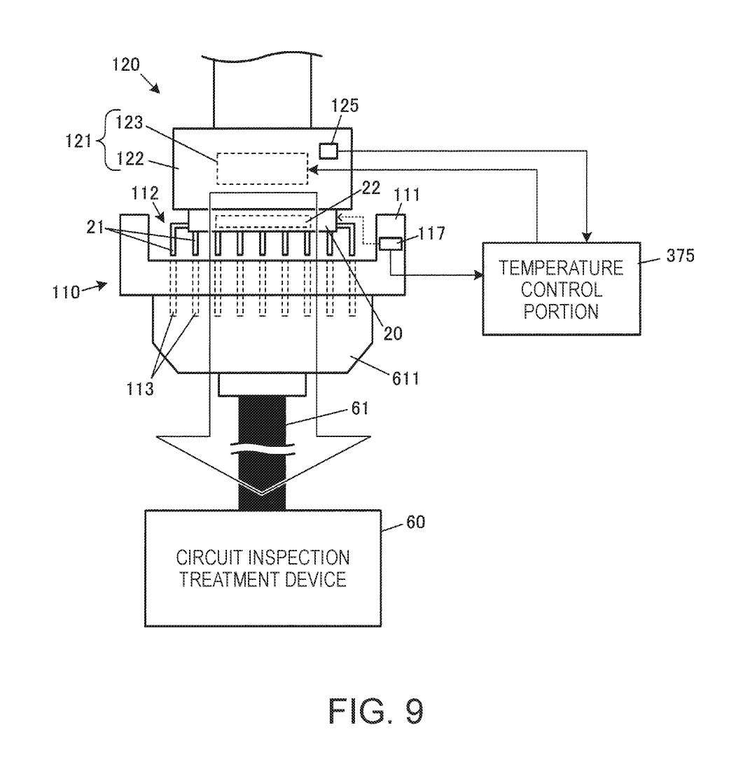

In the above-described embodiment, the heat flows moving through the socket position P_{SKT} are used as the examples of the heat flow Q₂ moving along the second heat flow path, and the description is made using the socket temperature T_{SKT}. However, as shown in FIG. 9, a surface temperature T_{PKG} of the IC package 20 may be used instead of the socket temperature T_{SKT}. In this case, the surface temperature T_{PKG} of the IC package 20 maybe detected using a non-contact thermometer 117 such as an infrared radiation thermometer installed at an appropriate place. The installation position of the non-contact thermometer 117 is not particularly limited, and the non-contact thermometer 117 can be installed in, for example, the socket 111 or the like on which the IC package 20 is mounted. In FIG. 9, the position of the non-contact thermometer 117 is determined so that a side surface of the IC package 20 becomes a measurement target position when the IC package 20 is mounted on the socket 111.

In the above-described embodiment, the detected temperatures detected using the second temperature detector 115 are used as a reference socket temperature T_{SKT0} and the socket temperature T_{SKT}. However, the surface temperature or the bottom surface temperature of the socket 111 may be measured using the contact thermometer such as an infrared radiation thermometer and be used as the reference socket temperature T_{SKT0} and the socket temperature T_{SKT}.

In the above-described embodiment, the temperature of the heating portion 121 is detected using the first temperature detector 125 and is used as the heat source temperature T_{H}, thereby computing the IC temperature T_{IC}. However, a constitution in which the heat generation temperature of the hand heater 123 which is computed using the heat generation temperature computation portion 379 is used as the heat source temperature T_{H}, thereby computing the IC temperature T_{IC} may be employed.

In the above-described embodiment, the IC has been exemplified as the electronic circuit which is the measurement subject, and the IC test handler for inspecting the IC has been described, but the embodiment can also be applied to inspection apparatuses that inspect the electrical characteristics of electronic components (electronic devices), electronic component modules, and the like in the same manner.

In the above-described embodiment, the control device 30 has been described as a separate device from the circuit inspection treatment device 60, but the control device may be constituted of a single device having both functions.

The entire disclosure of Japanese Patent Application No. 2016-221167 filed on Nov. 14, 2016 is expressly incorporated by reference herein.

What is claimed is:

1. A temperature-measuring apparatus comprising:
a heat source capable of changing a heat generation temperature;
a temperature sensor that detects a temperature of a predetermined position other than a measurement target accommodated in a measurement subject; and
a temperature computation portion that computes a temperature of the measurement target on the basis of heat balance characteristics of the temperature of the measurement target, a temperature of the heat source, and the temperature of the predetermined position, the temperature of the heat source, and the detected temperature of the predetermined position.

2. The temperature-measuring apparatus according to claim 1, further comprising:
a control portion that controls the temperature of the heat source on the basis of the computed temperature of the measurement target.

3. The temperature-measuring apparatus according to claim 1, further comprising:
a mounting portion on which the measurement subject is mounted.

4. The temperature-measuring apparatus according to claim 3,
wherein the temperature sensor detects a temperature of the mounting portion as the temperature of the predetermined position.

5. The temperature-measuring apparatus according to claim 3, further comprising:
a conveyance portion that holds and conveys the measurement subject to the mounting portion and halts at a predetermined halt position during measurement,
wherein the heat source is provided in the conveyance portion.

6. The temperature-measuring apparatus according to claim 1,
wherein the temperature computation portion variably sets the heat balance characteristics depending on heat environments.

7. The temperature-measuring apparatus according to claim 6,
wherein the temperature computation portion variably sets the heat balance characteristics depending on the heat environments on the basis of any one of a temperature in an apparatus chassis and a convection degree.

8. An inspection apparatus comprising:
the temperature-measuring apparatus according to claim 1 in which the measurement target is an electronic circuit.

9. An inspection apparatus comprising:
the temperature-measuring apparatus according to claim 3 in which the measurement target is an electronic circuit and the mounting portion has a socket for the electronic circuit;
a circuit inspection treatment device which is installed in a predetermined space in the apparatus chassis, has an operation compensation temperature that is lower than the temperature of the heat source, and is connected to the socket with an electrical wire; and
a cooling device for cooling the circuit inspection treatment device,
wherein the temperature computation portion variably sets the heat balance characteristics depending on a heat environment in the predetermined space.

10. An inspection apparatus comprising:
the temperature-measuring apparatus according to claim 4 in which the measurement target is an electronic circuit and the mounting portion has a socket for the electronic circuit;
a circuit inspection treatment device which is installed in a predetermined space in the apparatus chassis, has an operation compensation temperature that is lower than the temperature of the heat source, and is connected to the socket with an electrical wire; and
a cooling device for cooling the circuit inspection treatment device,
wherein the temperature computation portion variably sets the heat balance characteristics depending on a heat environment in the predetermined space.

11. An inspection apparatus comprising:
the temperature-measuring apparatus according to claim 5 in which the measurement target is an electronic circuit and the mounting portion has a socket for the electronic circuit;
a circuit inspection treatment device which is installed in a predetermined space in the apparatus chassis, has an operation compensation temperature that is lower than the temperature of the heat source, and is connected to the socket with an electrical wire; and
a cooling device for cooling the circuit inspection treatment device,
wherein the temperature computation portion variably sets the heat balance characteristics depending on a heat environment in the predetermined space.

12. The inspection apparatus according to claim 9,
wherein the temperature sensor detects a temperature of a position close to the electrical wire in the socket as the temperature of the predetermined position.

13. A control method of a temperature-measuring apparatus including a heat source capable of changing a heat generation temperature and a temperature sensor that detects a temperature of a predetermined position other than a measurement target accommodated in a measurement subject, the control method including: computing a temperature of the measurement target on the basis of heat balance characteristics of the temperature of the measurement target, a temperature of the heat source, and the temperature of the predetermined position, the temperature of the heat source, and the detected temperature of the predetermined position.
